(19) United States
(12) Patent Application Publication
(10) Pub. No.: US 2011/0120861 A1
(43) Pub. Date: May 26, 2011

(54) POWER SUPPLY APPARATUS

(76) Inventors: Yoshikuni Horishita, Kanagawa (JP); Shinobu Matsubara, Kanagawa (JP); Atsushi Ono, Kanagawa (JP)

(21) Appl. No.: 12/999,085

(22) PCT Filed: Jun. 17, 2009
(86) PCT No.: PCT/JP2009/060989

§ 371 Date: Jan. 13, 2011

(30) Foreign Application Priority Data
Jun. 30, 2008 (JP) 2008-170807

(51) Int. Cl. C23C 14/34

(52) U.S. Cl. 204/298.08

(57) ABSTRACT

There is provided a power supply apparatus that is capable of suppressing the occurrence of anomalous electric discharge due to charge-up of a substrate and that is capable of forming a good thin film on a large-area substrate. The power supply apparatus of this invention has: a first discharge circuit that alternately charges predetermined potential at a predetermined frequency to a pair of targets that are in contact with a plasma; and a second discharge circuit that charges predetermined potential between the grounding and the electrode, out of the pair of electrodes, that is not charged with potential from the first discharge circuit. The second discharge circuit is provided with a reverse potential charging means for charging, at the time of polarity reversal, at least one of the electrodes with potential that is reverse to the output potential.

### TECHNICAL FIELD

The present invention relates to a power supply apparatus and, in particular, to a power supply apparatus to be used in applying power to targets in a sputtering apparatus.

### BACKGROUND ART

As a method of forming a predetermined thin film on a surface of a substrate to be processed such as glass or silicon wafer, there is known a sputtering method. The sputtering method is an art in which the ions in a plasma atmosphere are accelerated and collided onto targets which are formed into a predetermined shape depending on the composition of the thin film to be formed on the surface of the substrate, and in which the sputtered particles (atoms of the targets) are scattered for getting adhered and deposited on the surface of the substrate to thereby form a predetermined thin film. Recently the method is used, in the process of manufacturing a flat panel display (FPD), to form a thin film such as an ITO and the like on a large-area substrate.

The following is known as a sputtering apparatus in which a thin film can be efficiently formed at a constant film thickness on a large-area substrate. In other words, this sputtering apparatus has: a plurality of targets of the same shape which are disposed at an equal distance from one another, opposite to the substrate to be processed in a vacuum chamber; and an AC power supply (power supply apparatus) which charges a predetermined potential to those respective targets which make pairs, out of the disposed targets, at a predetermined frequency while alternately changing the polarity (by reversing the polarity). While introducing a predetermined sputtering gas in a vacuum, output is made through the AC power supply to the targets that make pairs. By alternately switching each of the targets between an anode electrode and a cathode electrode, glow discharge is caused to be generated between the anode electrode and the cathode electrode. Plasma atmosphere is thus formed to thereby sputter each of the targets (see, e.g., patent document 1).

In the sputtering apparatus using the above-mentioned AC power source, during sputtering, electrical charge-up that has been built up on the target surface will be cancelled when an opposite phase voltage is charged. Therefore, even in case targets made of oxides and the like are used, anomalous electric discharge (arcing) attributable to the charge-up will be restrained or suppressed. On the other hand, the substrate that is potentially insulated or in a suspended state in the sputtering chamber will also be charged up. The charge-up on the surface of the substrate will ordinarily be neutralized, e.g., by the sputtered particles and ionized sputtering gas ions, and will disappear.

However, in case the electric power application (output) to the targets is increased in order to accelerate the sputtering speed, or in case the plasma density in the neighborhood of the target surface is increased by increasing the magnetic field strength on the target surface, the electrical charge-up on the surface of the substrate per unit time will be increased and, as a result, tends to stay on the surface of the substrate. Further, in case a transparent conductive film such as an ITO film and the like is formed on the surface of the substrate on which a metallic film or an insulating film that constitutes the electrodes, e.g., in the FPD manufacturing process has already been formed, electrical charge-up becomes easier to build up on the insulting film on the surface of the substrate.

In the sputtering apparatus that uses the above-mentioned AC power source, since electric discharge occurs between a pair of targets during sputtering, the discharge current flows only between the targets. Therefore, based on the grounding potential (the sputtering apparatus itself is ordinarily grounded), the potential of the plasma is ordinarily lower than that of the grounding. As a result, when the electrical charge-up gets built up on the substrate to be processed (or on the insulating film formed on the surface of the substrate to be processed), the above-mentioned known AC power source was not able to prevent the electrical charge-up from getting built up.

As described, once the electrical charge-up gets built up on the substrate (or on an insulating film formed on the surface of the substrate), there are cases where the electrical charge-up is instantly transferred, due to the potential difference, to a mask plate in the neighborhood between, e.g., the substrate and the grounded mask plate that is disposed in the peripheral portion of the substrate. Due to this phenomenon, an anomalous electric discharge (arcing) takes place. Once the anomalous electric discharge is generated, the film on the surface of the substrate is liable to be damaged, resulting in products of poor quality. Or else, a problem will happen in that particles will be generated, and the like, whereby good film forming will be disturbed.

### Patent Document 1: JP-A-2005-290550

### DISCLOSURE OF THE INVENTION

### [Problems to be Solved by the Invention]

In view of the above points, this invention has a problem of providing a power supply apparatus which is capable of suppressing the occurrence of anomalous electric discharge due to charge-up of the substrate and which is capable of forming a good thin film on a large-area substrate.

### [Means for Solving the Problems]

In order to solve the above problems, the power supply apparatus according to this invention comprises: a first discharge circuit which charges a pair of electrodes in contact with a plasma with a predetermined potential by alternately reversing polarity at a predetermined frequency; and a second discharge circuit which charges predetermined potential between the grounding and the electrode, out of the pair of electrodes, that is not charged with potential from the first discharge circuit. The second discharge circuit has a reverse potential charging means for charging, at the time of polarity reversal, at least one of the electrodes with a potential that is reverse to an output potential.

According to this invention, in case an output is made to any one of the electrodes, there will be generated a path for the discharge current to flow by the second discharge circuit through the grounding to the other of the electrodes, in addition to the path for the discharge current to flow by the first discharge circuit from the said one of the electrodes to the other of the electrodes. Then, at the time of polarity reversal, the potential that is opposite to the output potential is charged to at least one of the electrodes through the reverse potential charging means.

As described above, according to this invention, an arrangement has been employed in which reverse potential is charged to the electrode at the time of polarity reversal. Therefore, suppose that this invention is applied to a sputtering apparatus which is constructed to charge a predetermined AC potential to the paired targets by alternately changing the polarity at a predetermined frequency. Then, each time the target is charged with reverse potential, since the substrate that is disposed inside the sputtering chamber in a state of being potentially insulated or floated and the targets that serve as the electrodes are capacitively coupled together, the electrical charge-up built on the substrate tends to flow to the targets. As a result, even in case the power to be applied to the targets is intensified, and/or the magnetic strength on the surface of the targets is made stronger to thereby increase the plasma density near the surfaces of the targets, the electrical charge-up can efficiently be prevented from getting built up on the surfaces of the targets. The occurrence of the anomalous electric discharge due to the charge-up on the substrate can be suppressed, and good forming of a thin film on a large-area substrate becomes possible at a high productivity.

In this invention, preferably the first discharge circuit has: a DC power supply source; and a bridge circuit that is constituted by switching elements connected to a positive DC output and a negative DC output from the DC power supply source. The first discharge circuit is adapted to control the operation of each of the switching elements in the bridge circuit so as to output to the pair of the electrodes. The second discharge circuit has another DC power supply source, an end of the positive DC output from said another DC power supply source is grounded, and an end of the negative DC output is connected to the pair of electrodes through other switching elements that are interlocked with operations of the switching elements in the bridge circuit.

In addition, preferably the reverse potential charging means has: a DC power supply source that is connected to the positive and negative DC outputs of the second discharge circuit; and switching elements that control the charging of reverse potential from the DC power source to each of the electrodes.

The second discharge circuit preferably has a diode in the positive DC output with ground side thereof serving as cathode. Then, in case there has occurred an arcing for some cause or other, the reverse current to the second discharge circuit can advantageously be prevented.

In this invention, preferably the electrodes are targets disposed in a processing chamber in which sputtering is performed.

### BEST MODE FOR CARRYING OUT THE INVENTION

With reference to the accompanying drawings a description will now be made of a power supply apparatus E according to an embodiment of this invention. The power supply apparatus E is used to charge (or gives an output to) a pair of targets T1, T2, which serve as electrodes in contact with a plasma P, with AC pulsed potential at a predetermined frequency, the targets being disposed opposite to a substrate S which is present inside a vacuum chamber (processing chamber) M1, e.g., of a sputtering apparatus M. The power supply apparatus E has: a first discharge circuit E1 and a second discharge circuit E2; and a control means C for making an overall control of the operation, and the like of switching elements (to be described hereinafter) which are disposed in the first discharge circuit E1 and the second discharge circuit E2 (see FIG. 1).

The first discharge circuit E1 has a DC power supply source 1 which enables the supply of DC power. Although not illustrated, the DC power supply source 1 has: an input part which receives an input, e.g., of commercial AC power supply (3-phase, AC 200 V or 400 V); and a rectifying circuit which is made up of diodes for converting the inputted AC power to DC power. The DC power supply source 1 thus outputs DC power to an oscillation part through a positive DC power line 11a and a negative DC power line 11b. Between the DC power lines 11a, 11b there is provided a switching transistor which is controlled by a control means 3 (C) through an output oscillation driver circuit (not illustrated) so that the supply of DC power to the oscillation part can be controlled.

The oscillation part has a bridge circuit 12 which is made up of a first through a fourth, a total of four, switching transistors (switching elements) SW11 through SW14 which are connected between the positive and the negative DC power lines 11a, 11b. The output lines 13a, 13b from the bridge circuit 12 are respectively connected to the pair of targets T1, T2. The ON or OFF switching of each of the switching transistors SW11 through SW14 is controlled by the control means C through a driver circuit for output oscillation (not illustrated). The switching of each of the switching transistors SW11 through SW14 is controlled such that the timing is reversed of switching ON or OFF, e.g., of the first and the fourth switching transistors SW11, SW14 and of the second and the third switching transistors SW12, SW13. Predetermined pulsed potentials are thus charged to the pair of targets T1, T2 by alternately changing the polarity at a predetermined frequency (e.g., 1 to 10 kHz).

If each of the switching transistors SW11 through SW14 is switched in a state in which DC power is being outputted from the DC power supply source 1, the switching loss of the switching transistors will become large. Therefore, it is necessary to arrange such that the durability of each of the switching transistors SW11 through SW14 is improved. As a solution, between the positive and the negative DC output lines 11a, 11b from the DC power supply source 1, there is disposed a switching transistor SW15 for output short-circuiting, in which the ON or OFF switching is controlled by the control means C through the output oscillation driver circuit (not illustrated).

In a state in which the switching transistor SW15 for output short-circuiting is short-circuited (i.e., in a state in which output to the targets T1, T2 is cut off), switching is arranged to be made of each of the switching transistors SW11 through SW14 of the bridge circuit 12 (see FIG. 3). In other words, in a state in which the switching transistor SW15 is short-circuited (ON), the first and the fourth switching transistors SW11, SW14, for example, are switched ON. Thereafter, the short-circuiting of the switching transistor SW15 is released (OFF) to thereby output to one T1 of the targets (i.e., negative pulsed potential is charged to the target T1). Subsequently, the switching transistor SW15 is short-circuited again and switch OFF the first and the fourth switching transistors SW11, SW14, and the second and the third switching transistors SW12, SW13 are switched ON. Thereafter, the switching transistor SW15 is switched OFF to thereby output to the other T2 of the targets (i.e., negative pulsed potential is charged to the target T2).

According to this arrangement, the switching loss that occurs at the time of outputting to the targets T1, T2 occurs only in the switching transistor SW15, while little or no switching loss occurs to each of the switching transistors SW11 through SW14. As a result, without using a high-performance switching element, a high durability can be attained. In addition, there is required no sufficient heat-radiating mechanism that would otherwise be required in case the switching losses occur in the four switching elements. A lower cost can therefore be attained with this arrangement.

The second discharge circuit E2 is provided with a DC power supply source 2 that is of the same construction as the one in the first discharge circuit E1. The positive DC power line 21a from the DC power supply source 2 is connected to the grounded vacuum chamber M1. Further, the negative DC power line 21b from the DC power supply source 2 is branched and is connected to the output lines 13a, 13b, respectively, of the first discharge circuit E1. In this case, the branch lines 22a, 22b from the negative DC power line 21b are respectively provided with switching transistors SW21, SW22 which are actuated in interlocking with the switching transistors SW11 through SW14 of the bridge circuit 13.

The switching ON or OFF of both the switching transistors SW21, SW22 is controlled by the control means C through the output oscillation driver circuit (not illustrated). For example, in case one T1 of the targets is being charged with electric power by the first discharge circuit E1 in a state in which the first and the fourth switching transistors SW11, SW14 are switched ON, switching transistor SW21 is switched ON and predetermined electric power is arranged to be applied to the other T2 of the targets by the second discharge circuit (see FIG. 3).

Suppose that each of the targets T1, T2 is sputtered by applying power to the pair of targets T1, T2 by the first and the second discharge circuits E1, E2 while introducing a gas such as Ar and the like in a constant flow amount through a gas introducing means (not illustrated) in a state in which the vacuum chamber M1 is kept to a predetermined vacuum degree. Then, when the first and the fourth switching transistors SW11, SW14, for example, are switched ON (in this case, the second and the third switching transistors SW12, SW13 are in a state of being switched OFF), the discharge current Iac flows from one T1 of the targets to the other T2 thereof by the first discharge circuit E1. Also, when the switching transistor SW21 is switched ON (in this case, the switching transistor SW21 is in a state of being switched OFF), the discharge current Idc is caused to flow by the second discharge circuit E2 from the grounded vacuum chamber M1 to the other T2 of the targets.

Then, when reversing is made of the timing of ON or OFF of the first and the fourth switching transistors SW11, SW14 and of the second and the third switching transistors SW12, SW13 of the first discharge circuit E1, the timing is also reversed of ON or OFF of each of the switching transistors SW21, SW22 of the second discharge circuit E2, so that an output can be made to the pair of targets T1, T2 at a predetermined frequency. According to this arrangement, each of the targets T1, T2 is alternately switched to the anode electrode and to the cathode electrode. Glow discharge is caused to be generated between the anode electrode and the cathode electrode and between the cathode electrode and the grounding so as to form a plasma atmosphere. Each of the targets T1, T2 is thus sputtered.

As described so far, the power supply apparatus E according to this embodiment has a path in which the discharge current Idc flows between one T1 or T2 of the targets and the grounding, in addition to the path in which the discharge current Iac flows between the pair of targets T1, T2. Therefore, in case the discharge current flows only between the pair of targets as is the case with the known art, plasma tends to be partially generated only in front of the target that receives an output at the time of low frequency. On the other hand, in the power supply apparatus E according to the embodiment of this invention, plasma P will be generated over the front side of both the targets T1, T2 (see FIG. 1). As a result, at the time of forming a predetermined thin film on the surface of the substrate S, the film thickness distribution can be easily made uniform.

Also the second discharge circuit E2 shall preferably have the following arrangement, i.e., a switching transistor SW23 for output short-circuiting is disposed between the positive and the negative DC power lines 21a, 21b. In the same manner as in the above-mentioned first discharge circuit E1, the switching loss, that occurs at the time of outputting to the targets T1, T2, is thus arranged to occur only in the switching transistor SW23.

In the sputtering apparatus M provided with the above-mentioned power supply apparatus E, the electrical charge-up that is built up on the surface of the target during sputtering will be cancelled when an opposite-phase voltage is charged. Therefore, even in case a target of oxides and the like is used, the occurrence of anomalous electric discharge (arcing) attributable to the charge-up of the target will be suppressed. On the other hand, the substrate S that is in a potentially insulated or floated state inside the vacuum chamber M1 will also be charged up. However, the electrical charge-up on the surface of the substrate S will ordinarily be neutralized, e.g., by the sputtered particles or the ionized sputtering gas ions, and will disappear.

However, if the power to be applied, e.g., to the targets T1, T2 is set to a large value in order to increase the sputtering speed, the electrical charge-up potential e on the surface of the substrate S per unit time will increase, whereby the electrical charge-up is likely to be built up on the surface of the substrate S. Once the electrical charge-up gets built up on the substrate S in this manner, there will be cases where the electrical charge-up will instantly be transferred to the grounded mask plate due to potential difference at a neighboring portion between the substrate S and the grounded mask plate M2 which is disposed around the substrate S. Due to this transfer, anomalous electric discharge (arcing) may sometimes take place. In this case, problems occur in that the film on the surface of the substrate S will be damaged, giving rise to a poor-quality product, and in that particles will be generated, thereby impairing formation of acceptable thin films. Therefore, it is preferable for the power supply apparatus E to be capable of efficiently suppressing or restricting the building up of the electrical charge-up to the surface of the substrate S.

As a solution, in the embodiment of this invention, between the positive DC output line 21a of the second discharge circuit E2 and the branch lines 22a, 22b, there is disposed a reverse pulse generating circuit (reverse potential charging means) 3. The reverse pulse generating circuit 3 is provided with: a DC pulsed power supply 31 having a known construction; and switching transistors SW31, SW32 which control the charging of the positive pulse potential from the DC pulsed power supply 31 to the targets T1, T2 (see FIG. 2).

The following arrangement has further been made, i.e., in order to reverse the ON or OFF timing between the first and the fourth switching transistors SW11, SW14 and between the second and the third switching transistors SW12, SW13 of the first discharge circuit E1, and also in order to reverse the ON or OFF timing of each of the switching transistors SW21, SW22 of the second discharge circuit E2, each time the switching transistors SW15, SW23 are made to be in a short-circuited state (ON), the switching transistors SW31, SW32 are switched ON so that the pair of targets T1, T2 are charged with positive pulsed potential Vp (see FIGS. 2 and 3).

Once the pair of targets T1, T2 are charged with positive pulsed potential Vp at the time of polarity reversal, the electrical charge-up potential e that is built up on the substrate S flows to the targets T1, T2 since the substrate S and the targets T1, T2 are capacitively coupled to each other in the vacuum chamber M1. As a result, even in case the power to be applied to the targets T1, T2 is made larger, the power supply apparatus E can efficiently prevent the electrical charge-up potential e from getting built up on the surface of the substrate S. In this manner, the occurrence of anomalous electric discharge due to charge-up of the substrate S can be suppressed. It becomes thus possible to form a good thin film on a large-sized substrate S at high productivity.

By the way, during the above-mentioned glow discharge, there are cases where arcing (anomalous electric discharge) may take place for some cause or other. There is thus a possibility that reverse current flows at the time of occurrence of anomalous electric discharge, thereby damaging the second discharge circuit E2. Therefore, the positive DC power line 21a is provided with a diode 24 with the ground side serving as cathode.

In addition, since the outputs from the DC power supply sources 1, 2 have constant voltage characteristics, the capacitance component (capacitance) becomes more dominant than does the inductance component. If the capacitance component (capacitance) is dominant in this manner, the impedance on the side of the plasma load becomes small at the time of occurrence of arcing, whereby the output and the plasma load are coupled so as to be rapidly discharged to the output side.

As a solution, each of the negative DC output lines 11b, 21b of the first and the second discharge circuits E1, E2 is provided with an inductor 4 having a larger inductance value than the inductance value of the plasma. The rate of rise in electric current per unit time at the time of occurrence of arcing is thus arranged to be limited.

In addition, in case the inductor 4 is disposed as described above, there is provided a diode 5 and a resistor 6 which are in parallel with the above-mentioned inductor 4 and are connected in series with each other in order to suppress the overvoltage that may occur at the time of switching each of the switching elements. According to this arrangement, at the time of switching each of the switching transistors SW11 through SW14 and SW21, SW22 in the first and the second discharge circuits E1, E2 (at the time of polarity reversal), the output to the targets T1, T2 initially becomes constant voltage characteristics, and the output current comes to gradually increase and thereafter (when the output current reaches a predetermined value) the output becomes constant current characteristics. As a result, the overvoltage can be prevented from occurring at the time of polarity reversal at each of the electrodes, and the occurrence of arcing due to overcurrent can be suppressed.

In this embodiment, the inductor 4, the diode 5, and the resistor 6 are respectively disposed in the negative DC output lines 11b, 21b. They may, however, be disposed in the negative DC output lines 11a, 21a or in both of them.

Further, in this embodiment, a description has been made, as the reverse potential charging means 3, of the one which is constituted by the DC pulsed power supply 31 and the switching transistors SW31, SW32. However, as long as the positive potential can be charged at the time of polarity reversal, this invention is not limited to the above-mentioned example. For example, an arrangement may be made that a transformer is provided so that the positive pulsed potential can be charged.

Further, in this embodiment, a description has been made of an example in which the pair of targets T1, T2 disposed in the vacuum chamber M1 output through a single power supply apparatus E. Without being limited thereto, this invention is applicable also to an example in which, out of a plurality of targets of the same shape that are disposed at an equal distance from one another inside a vacuum chamber so as to lie opposite to the substrate, those targets respectively making a pair have assigned thereto a power supply apparatus of the same construction, whereby each of the targets is charged with pulsed voltage at a given frequency. This invention may also be applied to a case in which an output is made to a pair of targets by a plurality of power supply apparatuses.

### BRIEF DESCRIPTION OF THE DRAWINGS

FIG. 1 is a schematic diagram showing the arrangement of a power supply apparatus of this invention.

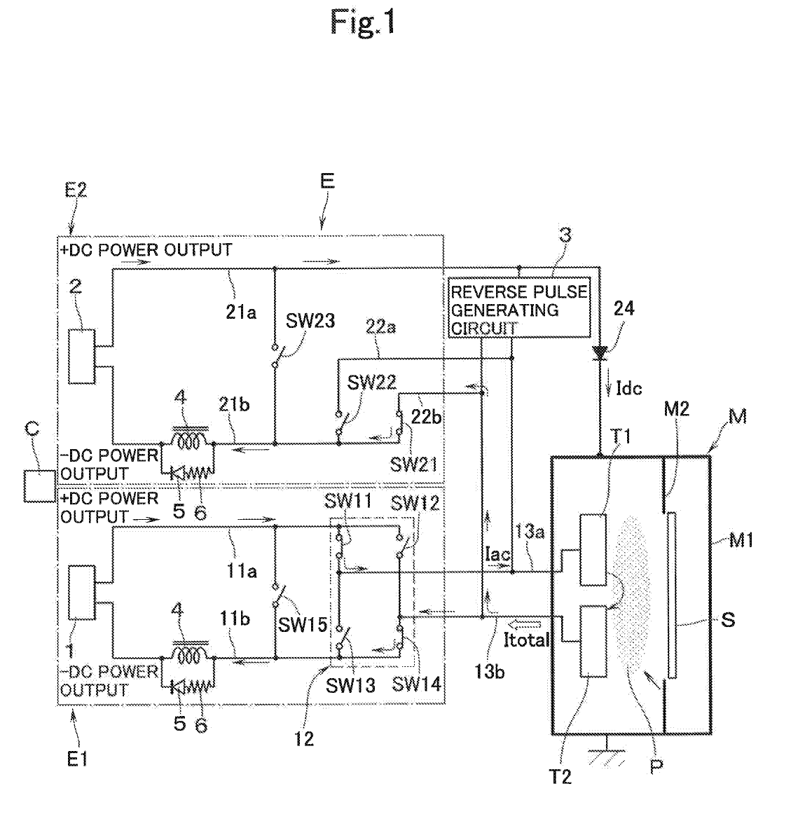

FIG. 2 is a schematic diagram showing a reverse potential generating circuit.

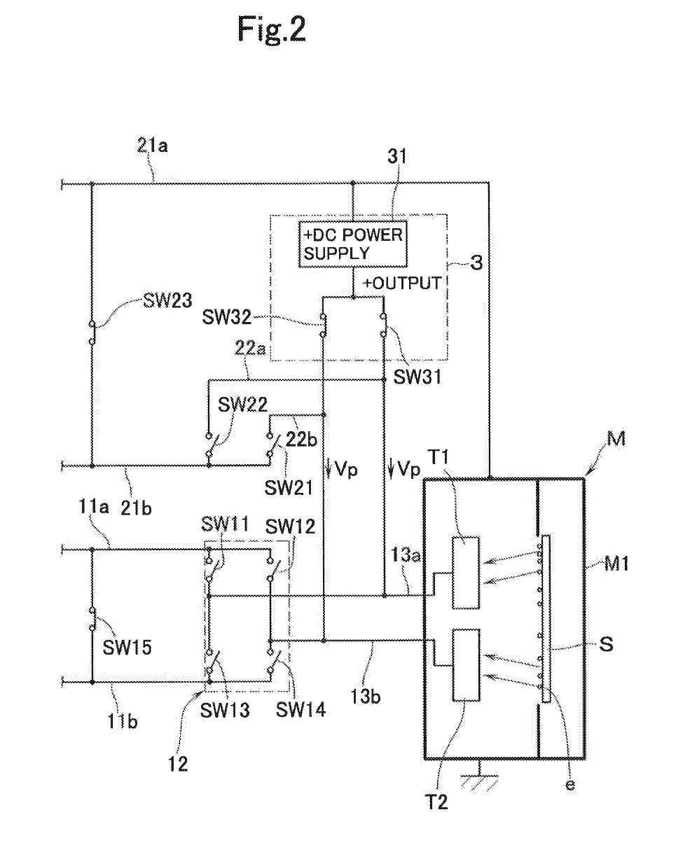

FIG. 3 is a graph showing the output control of the power supply apparatus of this invention.

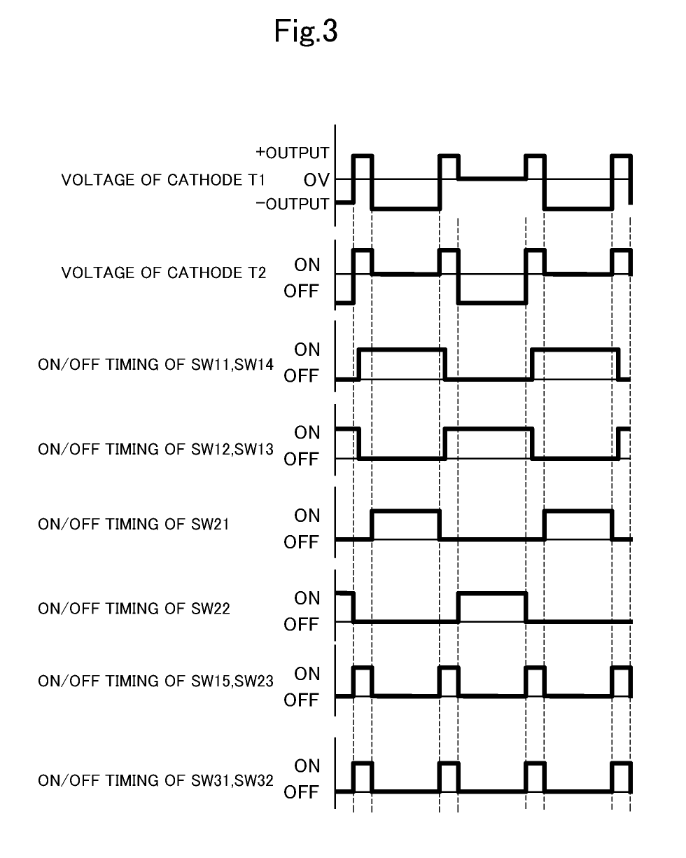

### DESCRIPTION OF REFERENCE NUMERALS AND CHARACTERS

1, 2 DC power supply source
12 bridge circuit
3 reverse pulse generating circuit (reverse potential charging means)
4 inductor
5, 24 diode
6 resistor
E power supply apparatus
E1 first discharge circuit
E2 second discharge circuit
M sputtering apparatus
SW11 through SW15 switching transistor (switching element)
SW21 through SW23 switching transistor (switching element)
T1, T2 electrode (target)

1. A power supply apparatus comprising:
a first discharge circuit which charges a pair of electrodes in contact with a plasma with a predetermined potential by alternately reversing polarity at a predetermined frequency; and
a second discharge circuit which charges predetermined potential between the grounding and the electrode, out of the pair of electrodes, that is not charged with the potential from the first discharge circuit,
wherein the second discharge circuit has a reverse potential charging means for charging, at a time of polarity reversal, at least one of the electrodes with a potential that is reverse to an output potential.

2. The power supply apparatus according to claim 1,
wherein the first discharge circuit has: a DC power supply source; and a bridge circuit that is constituted by switching elements connected to a positive DC output and a negative DC output from the DC power supply source, the first discharge circuit being adapted to control the operation of each of the switching elements in the bridge circuit so as to output to the pair of the electrodes, and
wherein the second discharge circuit has another DC power supply source, an end of the positive DC output from said another DC power supply source is grounded, and an end of the negative DC output is connected to the pair of electrodes through other switching elements that are interlocked with the operation of the switching elements in the bridge circuit.

3. The power supply apparatus according to claim 2, wherein the reverse potential charging means has: a DC power supply source that is connected to the positive DC output and the negative DC output of the second discharge circuit; and switching elements that control the charging of reverse potential from the DC power source to each of the electrodes.

4. The power supply apparatus according to claim 2, wherein the second discharge circuit has a diode in the positive DC output with ground side thereof serving as cathode.

5. The power supply apparatus according to claim 1, wherein the electrodes are targets disposed in a processing chamber in which sputtering is performed.

6. The power supply apparatus according to claim 3, wherein the second discharge circuit has a diode in the positive DC output with ground side thereof serving as cathode.

7. The power supply apparatus according to claim 2, wherein the electrodes are targets disposed in a processing chamber in which sputtering is performed.

8. The power supply apparatus according to claim 3, wherein the electrodes are targets disposed in a processing chamber in which sputtering is performed.

9. The power supply apparatus according to claim 4, wherein the electrodes are targets disposed in a processing chamber in which sputtering is performed.

10. The power supply apparatus according to claim 6, wherein the electrodes are targets disposed in a processing chamber in which sputtering is performed.
